(19) United States
(12) Patent Application Publication
(10) Pub. No.: US 2024/0136263 A1
(43) Pub. Date: Apr. 25, 2024

(54) ELECTRONIC PACKAGE

(71) Applicant: SILICONWARE PRECISION INDUSTRIES CO., LTD., Taichung (TW)

(72) Inventors: Hung-Kai WANG, Taichung (TW); Yih-Jenn JIANG, Taichung (TW); Don-Son JIANG, Taichung (TW); Yu-Lung HUANG, Taichung (TW); Men-Yeh CHIANG, Taichung (TW)

(73) Assignee: SILICONWARE PRECISION INDUSTRIES CO., LTD., Taichung (TW)

(21) Appl. No.: 18/064,404

(22) Filed: Dec. 12, 2022

(30) Foreign Application Priority Data
Oct. 20, 2022 (TW) 111140085

(51) Int. Cl. H01L 23/498; H01L 25/10; H01L 25/16

(52) U.S. Cl. CPC H01L 23/49816; H01L 23/49833; H01L 23/49838; H01L 23/49866; H01L 25/105; H01L 25/162; H01L 2225/1023; H01L 2225/1041; H01L 2225/1058

(57) ABSTRACT

An electronic package is provided, in which a first electronic module and a second electronic module are stacked via a plurality of first conductive structures and a plurality of second conductive structures, and the amount of solder of the first conductive structures is greater than the amount of solder of the second conductive structures, such that the electronic package can be configured with the first conductive structures and the second conductive structures according to the degree of warpage of the electronic package, so as to effectively disperse the stress to avoid the problem of warpage.

### BACKGROUND

### 1. Technical Field

The present disclosure relates to a semiconductor device, and more particularly, to an electronic package for stacking a plurality of electronic modules.

### 2. Description of Related Art

With the vigorous development of the electronic industry, electronic products are also gradually moving towards the trend of multi-function and high performance. Technologies currently used in the field of chip packaging include, for example, chip scale package (CSP), direct chip attached (DCA), package on package (PoP), or multi-chip module (MCM) and other packaging types.

FIG. 1 is a schematic cross-sectional view of a conventional semiconductor package 1. As shown in FIG. 1, in the semiconductor package 1, two package modules 1a, 1b are stacked on each other via a plurality of solder bumps 13, wherein the package module 1a includes at least one circuit structure 10a, an electronic element 11a disposed on and electrically connected to the circuit structure 10a, and an encapsulation layer 12a encapsulating the electronic element 11a, wherein the package module 1b includes a circuit structure 10b, electronic elements 11b disposed on and electrically connected to the circuit structure 10b, and an encapsulation layer 12b encapsulating the electronic elements 11b, so that the solder bumps 13 are electrically connected to the circuit structures 10a, 10b, wherein the lower package module 1a has the circuit structures 10a disposed on opposite sides of the encapsulation layer 12a, so a plurality of copper pillars 17 for electrically connecting the two circuit structures 10a are arranged in the encapsulation layer 12a.

The aforementioned semiconductor package 1 is disposed on a circuit board 19 via a plurality of conductive bumps 191 and solder balls 190 with the underlying circuit structure 10a.

However, in the conventional semiconductor package 1, due to the difference in the number of layers and/or wiring of the circuit structures 10a, 10b, or the difference in the specification, number and/or size of the electronic elements 11a, 11b, or the difference in the amount and/or material of the encapsulation layers 12a, 12b and other factors, the stress generated by the two package modules 1a, 1b cannot be evenly distributed, and thus the stress distribution of an area S between the two package modules 1a, 1b is different. If the stress at the corners is much greater than other places, the semiconductor package 1 is prone to deformation (i.e., warpage), causing the solder bumps 13 or the solder balls 190 to be detached, thereby leading to the reliability of the semiconductor package 1 not good.

Therefore, how to overcome the above-mentioned various problems of the prior art has become an urgent problem to be solved at present.

### SUMMARY

In view of the various deficiencies of the prior art, the present disclosure provides an electronic package, comprising: a first electronic module having a first side and a second side opposing the first side; a second electronic module stacked on the first side of the first electronic module, wherein an area between the first side of the first electronic module and the second electronic module is defined as a first interlayer, and an area outward from the second side of the first electronic module is defined as a second interlayer; a plurality of first conductive structures having solder material and disposed in the first interlayer; and a plurality of second conductive structures having solder material and disposed in the first interlayer, wherein a solder amount of the plurality of first conductive structures is greater than a solder amount of the plurality of second conductive structures.

In the aforementioned electronic package, each of the first conductive structures is a solder ball.

In the aforementioned electronic package, each of the second conductive structures includes a conductive pillar and a solder material formed on an end surface of the conductive pillar.

In the aforementioned electronic package, the plurality of first conductive structures and the plurality of second conductive structures are configured according to a magnitude of a stress in the first interlayer, such that a stress at positions where the plurality of first conductive structures are distributed in the first interlayer is greater than a stress at positions where the plurality of second conductive structures are distributed in the first interlayer.

In the aforementioned electronic package, the plurality of first conductive structures surround the plurality of second conductive structures.

In the aforementioned electronic package, the plurality of first conductive structures are further disposed in the second interlayer, and a number of the plurality of first conductive structures in the first interlayer is less than a number of the plurality of first conductive structures in the second interlayer.

In the aforementioned electronic package, the plurality of second conductive structures are further disposed in the second interlayer, and a number of the plurality of second conductive structures in the first interlayer is greater than a number of the plurality of second conductive structures in the second interlayer.

In the aforementioned electronic package, the present disclosure further comprises a plurality of third conductive structures disposed in the first interlayer and free of having solder. For example, each of the third conductive structures includes a first conductive pillar and a second conductive pillar stacked on each other, wherein the first conductive pillar is erected on the first electronic module, and the second conductive pillar is erected on the second electronic module, such that an end surface of the first conductive pillar and an end surface of the second conductive pillar are in contact with each other in the first interlayer.

Further, the plurality of first conductive structures, the plurality of second conductive structures and the plurality of third conductive structures are configured according to a magnitude of a stress in the first interlayer, such that a stress at positions where the plurality of first conductive structures are distributed in the first interlayer is greater than a stress at positions where the plurality of second conductive structures are distributed in the first interlayer, and a stress at positions where the plurality of second conductive structures are distributed in the first interlayer is greater than a stress at positions where the plurality of third conductive structures are distributed in the first interlayer.

Alternatively, the plurality of first conductive structures, the plurality of second conductive structures and the plurality of third conductive structures are sequentially arranged in a symmetrical manner from outside to inside in the first interlayer. For example, the plurality of second conductive structures surround the plurality of third conductive structures.

In addition, the plurality of third conductive structures are further disposed in the second interlayer, and a number of the plurality of third conductive structures in the first interlayer is equal to a number of the plurality of third conductive structures in the second interlayer.

As can be seen from the above, in the electronic package of the present disclosure, the first conductive structures and the second conductive structures with different amounts of solder can be configured in the first interlayer according to the degree of warpage of the electronic package, so as to effectively disperse the stress and avoid the problem of stress concentration. Therefore, compared with the prior art, the electronic package of the present disclosure can avoid the problem of warpage, so as to improve the yield of the electronic package on the circuit board subsequently.

### BRIEF DESCRIPTION OF THE DRAWINGS

FIG. 1 is a schematic cross-sectional view of a conventional semiconductor package.

FIG. 2 is a schematic cross-sectional view of an electronic package according to the present disclosure.

FIG. 3A and FIG. 3B are schematic top views of different interlayers of FIG. 2.

### DETAILED DESCRIPTIONS

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “third,” “a,” “one” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

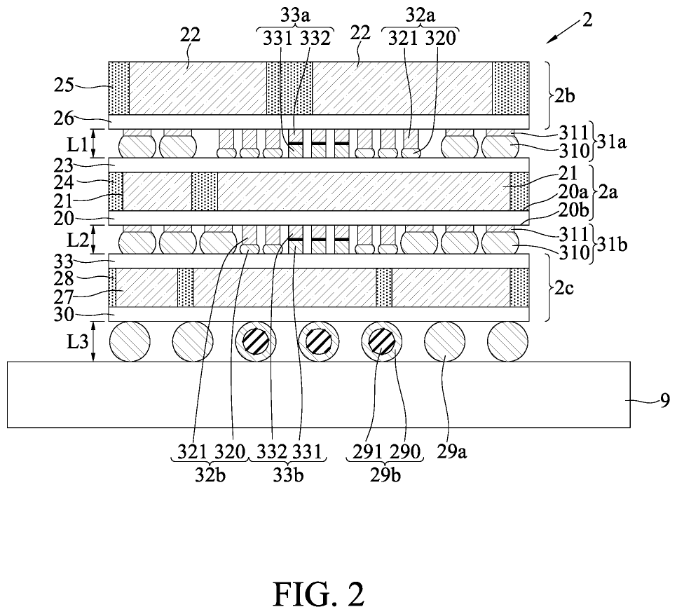

FIG. 2 is a schematic cross-sectional view of an electronic package 2 according to the present disclosure. As shown in FIG. 2, the electronic package 2 includes: a first electronic module 2a, a second electronic module 2b, a plurality of first conductive structures 31a, 31b, a plurality of second conductive structures 32a, 32b, and a plurality of third conductive structures 33a, 33b, wherein the members of the first conductive structures 31a, 31b, the second conductive structures 32a, 32b and the third conductive structures 33a, 33b are different from each other.

The first electronic module 2a includes a first cladding layer 24, at least one first electronic element 21 embedded in the first cladding layer 24, a first carrier structure 20 disposed on one side of the first cladding layer 24 and electrically connected to the first electronic element 21, and a wiring/routing structure 23 disposed on the other side of the first cladding layer 24.

In an embodiment, the first carrier structure 20 is defined with a first side 20a and a second side 20b opposing the first side 20a, and the first carrier structure 20 may be, for example, a package substrate having a core layer and a circuit structure, a package substrate with a coreless circuit structure, a through-silicon interposer (TSI) with conductive through-silicon vias (TSVs), or other types of board. The first carrier structure 20 includes at least one dielectric layer (not shown) and at least one circuit layer (not shown) bonded with the dielectric layer. For example, the circuit layer is formed by a redistribution layer (RDL) manufacturing method, and the material for forming the circuit layer is copper. The material for forming the dielectric layer is such as polybenzoxazole (PBO), polyimide (PI), prepreg (PP), and other dielectric materials. It should be understood that the first carrier structure 20 can also be other boards for carrying chips, such as lead frames, wafers, or other boards with metal routings, etc., and is not limited to above.

Furthermore, the first electronic element 21 is disposed on the first side 20a of the first carrier structure 20 and is electrically connected to the circuit layer of the first carrier structure 20, and the first electronic element 21 is an active element, a passive element, or a combination of the active element and the passive element, etc., wherein the active element is such as a semiconductor chip, and the passive element is such as a resistor, a capacitor, or an inductor. In an embodiment, the first electronic element 21 is a semiconductor chip, and a plurality of (e.g., two as shown in FIG. 2) the first electronic elements 21 are disposed on the first carrier structure 20. It should be understood that there are many methods for the first electronic element 21 to be electrically connected to the first carrier structure 20, such as wire-bonding method, flip-chip method, embedding method, or other methods, and the present disclosure is not limited to as such.

In addition, the first cladding layer 24 is formed on the first side 20a of the first carrier structure 20 to encapsulate the first electronic element 21, and the first cladding layer 24 is made of an insulating material, such as polyimide (PI), dry film, epoxy resin, molding compound, or other packaging materials.

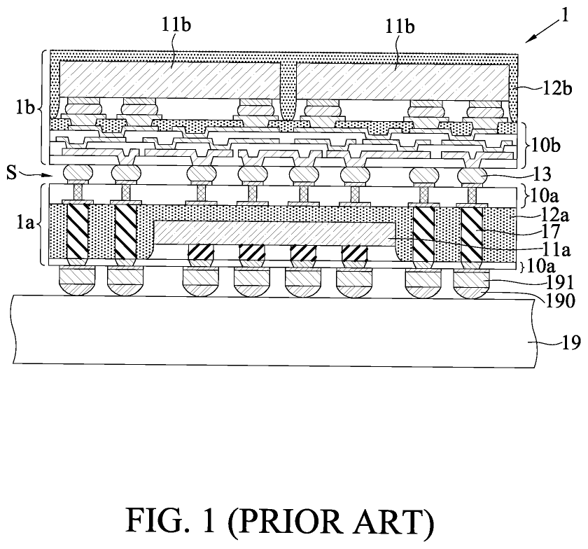

In addition, the routing structure 23 includes at least one insulating layer (not shown) and a redistribution layer (RDL) (not shown) disposed on the insulating layer. For example, the material for forming the redistribution layer is copper, and the material for forming the insulating layer is a dielectric material such as polybenzoxazole (PBO), polyimide (PI), and prepreg (PP). It should be understood that the routing structure 23 and the first carrier structure 20 can be electrically connected to each other via at least one conductive structure (e.g., the copper pillar 17 as shown in FIG. 1) formed in the first cladding layer 24.

The second electronic module 2b includes a second cladding layer 25, at least one second electronic element 22 embedded in the second cladding layer 25, and a second carrier structure 26 disposed on the second cladding layer 25 and electrically connected to the second electronic element 22, so that the first conductive structures 31a, the second conductive structures 32a and the third conductive structures 33a are connected between the second carrier structure 26 and the routing structure 23, such that the second electronic module 2b is stacked on the first electronic module 2a via the first conductive structures 31a, the second conductive structures 32a and the third conductive structures 33a, wherein the area between the first electronic module 2a and the second electronic module 2b is defined as a first interlayer L1, and the outward area of the second side 20b of the first carrier structure 20 of the first electronic module 2a is defined as a second interlayer L2.

It should be understood that the structure of the first electronic module 2a and the structure of the second electronic module 2b may be the same or different, and the size (e.g., volume or width) of the first electronic module 2a may be greater than, equal to, or smaller than the size of the second electronic module 2b.

In an embodiment, the second carrier structure 26 is, for example, a package substrate having a core layer and a circuit structure, a package substrate with a coreless circuit structure, a through-silicon interposer (TSI) with conductive through-silicon vias (TSVs), or other types of board. The second carrier structure 26 includes at least one dielectric layer (not shown) and at least one circuit layer (not shown) bonded with the dielectric layer. In an embodiment, the circuit layer is formed by a redistribution layer (RDL) manufacturing method, and the material for forming the circuit layer is copper. The material for forming the dielectric layer is such as polybenzoxazole (PBO), polyimide (PI), prepreg (PP), and other dielectric materials. It should be understood that the second carrier structure 26 can also be other boards for carrying chips, such as lead frames, wafers, or other boards with metal routings, etc., and is not limited to above.

Furthermore, the second electronic element 22 is disposed on the second carrier structure 26 and is electrically connected to the circuit layer of the second carrier structure 26, and the second electronic element 22 is an active element, a passive element, or a combination of the active element and the passive element, etc., wherein the active element is such as a semiconductor chip, and the passive element is such as a resistor, a capacitor, or an inductor. In an embodiment, the second electronic element 22 is a semiconductor chip, and a plurality of (e.g., two as shown in FIG. 2) the second electronic elements 22 are disposed on the second carrier structure 26. It should be understood that there are many methods for the second electronic element 22 to be electrically connected to the second carrier structure 26, such as wire-bonding method, flip-chip method, embedding method, or other methods, and the present disclosure is not limited to as such.

In addition, the second cladding layer 25 is formed on the second carrier structure 26 to encapsulate the second electronic elements 22. In an embodiment, the second cladding layer 25 is made of an insulating material, such as polyimide (PI), dry film, epoxy resin, molding compound, or other packaging materials. It should be understood that the material of the first cladding layer 24 and the material of the second cladding layer 25 may be the same or different.

The first conductive structures 31a, 31b include solder materials 310, such as solder balls of type C4, which are disposed in the first interlayer L1 (i.e., between the second carrier structure 26 and the routing structure 23) and the second interlayer L2 (i.e., on the second side 20b of the first carrier structure 20).

In an embodiment, the first conductive structures 31a, 31b further include electrical contact pads 311 for bonding the solder materials 310, wherein the electrical contact pads 311 are respectively disposed on the first carrier structure 20 of the second interlayer L2 and the second carrier structure 26 of the first interlayer L1. For example, the electrical contact pads 311 are formed on the second carrier structure 26, so that the solder materials 310 are formed on the electrical contact pads 311 and bonded to the redistribution layer of the routing structure 23; or, the electrical contact pads 311 are formed on the second side 20b of the first carrier structure 20, so that the solder materials 310 are formed on the electrical contact pads 311 and externally connected to other elements such as a package module 2c.

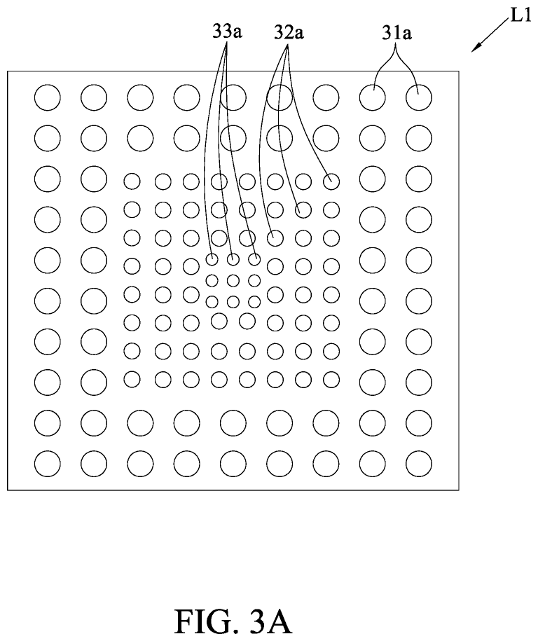

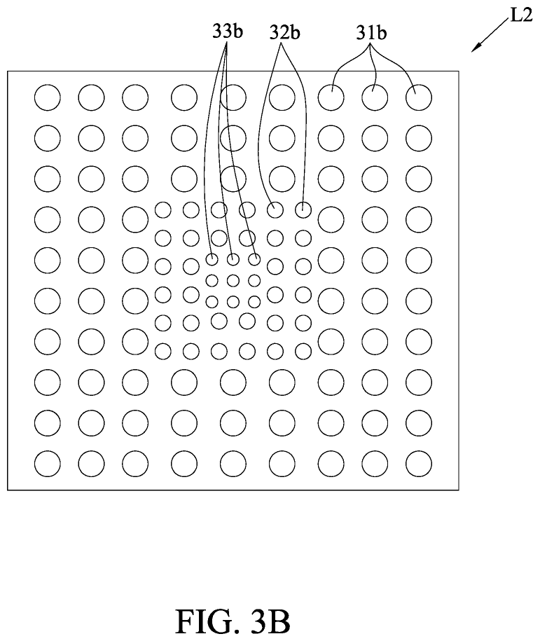

Furthermore, the number of the first conductive structures 31a of the first interlayer L1 is less than the number of the first conductive structures 31b of the second interlayer L2. For example, both the first interlayer L1 and the second interlayer L2 are rectangular regions. As shown in FIG. 3A, the first conductive structures 31a of the first interlayer L1 are arranged in two circles along the edge of the rectangular region; and as shown in FIG. 3B, the first conductive structures 31b of the second interlayer L2 are arranged in three circles along the edge of the rectangular region.

Furthermore, the first interlayer L1 and the second interlayer L2 are both rectangular regions, so that the first conductive structures 31a and the first conductive structures 31b are located at the edge of the first interlayer L1 and the edge of the second interlayer L2 respectively (especially at corners), as shown in FIG. 3A and FIG. 3B.

The second conductive structures 32a, 32b include solder materials 320 such as solder bumps and conductive pillars 321 such as of a micro-bump (t-bump) type, wherein the solder materials 320 and the conductive pillars 321 are disposed in the first interlayer L1 (i.e., between the second carrier structure 26 and the routing structure 23) and the second interlayer L2 (i.e., between the second side 20b of the first carrier structure 20 and the package module 2c).

In an embodiment, the conductive pillars 321 are metal pillars such as copper pillars, and the solder materials 320 are formed on ends of the conductive pillars 321. For example, the conductive pillars 321 are erected on the second carrier structure 26, so that the solder materials 320 are bonded to the redistribution layer of the routing structure 23; or, the conductive pillars 321 can be erected on the second side 20b of the first carrier structure 20, so that the solder materials 320 can be externally connected to other elements such as the package module 2c.

Furthermore, the number of the second conductive structures 32a of the first interlayer L1 is greater than the number of the second conductive structures 32b of the second interlayer L2. For example, as shown in FIG. 3A, the second conductive structures 32a of the first interlayer L1 are arranged in three circles corresponding to the edge of the rectangular region of the first interlayer L1; and as shown in FIG. 3B, the second conductive structures 32b of the second interlayer L2 are arranged in two circles corresponding to the edge of the rectangular region of the second interlayer L2.

Also, the first conductive structures 31a, 31b surround the second conductive structures 32a, 32b respectively, as shown in FIG. 3A and FIG. 3B.

In addition, the amount of solder of the first conductive structures 31a, 31b is greater than the amount of solder of the second conductive structures 32a, 32b.

Each of the third conductive structures 33a, 33b includes a first conductive pillar 331 and a second conductive pillar 332 stacked on each other, wherein the first conductive pillars 331 and the second conductive pillars 332 are metal pillars, which are disposed in the first interlayer L1 (i.e., between the second carrier structure 26 and the routing structure 23) and the second interlayer L2 (i.e., between the second side 20b of the first carrier structure 20 and the package module 2c).

In an embodiment, the first conductive pillars 331 and the second conductive pillars 332 are both copper pillars, and copper end surfaces of the first conductive pillars 331 and the second conductive pillars 332 are in contact with each other. For example, the first conductive pillars 331 are erected on the routing structure 23, and the second conductive pillars 332 are erected on the second carrier structure 26, so that end surfaces of the first conductive pillars 331 and end surfaces of the second conductive pillars 332 (the first conductive pillar 331 and the second conductive pillar 332 are two copper pillars) are in contact with each other in the first interlayer L1 to form the third conductive structures 33a; or, the first conductive pillars 331 can be erected on other elements such as the package module 2c, and the second conductive pillars 332 can be erected on the second side 20b of the first carrier structure 20, so that end surfaces of the first conductive pillars 331 and end surfaces of the second conductive pillars 332 (the first conductive pillar 331 and the second conductive pillar 332 are two copper pillars) are in contact with each other in the second interlayer L2 to form the third conductive structures 33b.

Furthermore, the number of the third conductive structures 33a in the first interlayer L1 is equal to the number of the third conductive structures 33b in the second interlayer L2. For example, as shown in FIG. 3A, the third conductive structures 33a of the first interlayer L1 are symmetrically arranged in nine groups in the middle of the rectangular region of the first interlayer L1; and as shown in FIG. 3B, the third conductive structures 33b of the second interlayer L2 are also symmetrically arranged in nine groups in the middle of the rectangular region of the second interlayer L2.

Furthermore, the amount of solder of the second conductive structures 32a, 32b is greater than the amount of solder of the third conductive structures 33a, 33b, and the second conductive structures 32a, 32b surround the third conductive structures 33a, 33b respectively, as shown in FIG. 3A and FIG. 3B.

In addition, the first, second and third conductive structures 31a, 32a, 33a are configured according to the stress in the first interlayer L1 (e.g., the first, second and third conductive structures 31a, 32a, 33a are arranged according to the magnitude of the stress in the first interlayer L1), so that the stress at positions where the first conductive structures 31a are distributed in the first interlayer L1 is greater than the stress at positions where the second conductive structures 32a are distributed in the first interlayer L1, and the stress at positions where the second conductive structures 32a are distributed in the first interlayer L1 is greater than the stress at positions where the third conductive structures 33a are distributed in the first interlayer L1. Similarly, the second interlayer L2 can also adopt the above configuration. In other words, the arrangement of the conductive structures between the layers can be configured based on the amount of solder, so that the first conductive structures 31a, 31b with the largest amount of solder, the second conductive structures 32a, 32b with the second largest amount of solder, and the third conductive structures 33a, 33b without solder are arranged in a symmetrical manner from outside to inside in order among the layers, as shown in FIG. 3A and FIG. 3B.

Therefore, in the electronic package 2 of the present disclosure, the first electronic module 2a and the second electronic module 2b are stacked mainly by the first conductive structures 31a, the second conductive structures 32a and the third conductive structures 33a of different structures, and more solder materials 310, 320 with better stress absorption effect are arranged on a region of the first interlayer L1 that is closer to the periphery, that is, the first conductive structures 31a with the largest amount of solder, the second conductive structures 32a with the second largest amount of solder, and the third conductive structures 33a without solder are sequentially arranged in the first interlayer L1 from outside to inside, so as to effectively disperse the stress and avoid the problem of stress concentration. Therefore, compared with the prior art, the electronic package 2 of the present disclosure can avoid the problem of warpage.

Furthermore, due to the small size and low resistance value of the copper pillar bonding aspect, it is suitable for applications such as high number of contacts (I/O), high signal transmission and low current, etc. Therefore, the third conductive structures 33a, 33b can be arranged between the layers according to requirements.

Also, the stress at the corners of the first interlayer L1 is less than the stress at the corners of the second interlayer L2. Therefore, by the design that the amount of solder at the corners of the first interlayer L1 is less than the amount of solder at the corners of the second interlayer L2 (that is, the number of the first conductive structures 31a at the corners of the first interlayer L1 is less than the number of the first conductive structures 31b at the corners of the second interlayer L2), not only the stress can be dispersed and the problem of stress concentration can be avoided, but also the amount of the solder material 310 can be saved.

On the other hand, the aforementioned package module 2c includes an encapsulation layer 28, at least one third electronic element 27 embedded in the encapsulation layer 28, a third carrier structure 30 disposed on one side of the encapsulation layer 28 and electrically connected to the third electronic element 27, and a routing structure 33 disposed on the other side of the encapsulation layer 28.

In an embodiment, the third carrier structure 30 is, for example, a package substrate having a core layer and a circuit structure, a package substrate with a coreless circuit structure, a through-silicon interposer (TSI) with conductive through-silicon vias (TSVs), or other types of board. The third carrier structure 30 includes at least one dielectric layer (not shown) and at least one circuit layer (not shown) bonded with the dielectric layer. For example, the circuit layer is formed by a redistribution layer (RDL) manufacturing method, and the material for forming the circuit layer is copper. The material for forming the dielectric layer is such as polybenzoxazole (PBO), polyimide (PI), prepreg (PP), and other dielectric materials. It should be understood that the third carrier structure 30 can also be other boards for carrying chips, such as lead frames, wafers, or other boards with metal routings, etc., and is not limited to above.

Furthermore, the third electronic element 27 is disposed on the third carrier structure 30 and is electrically connected to the circuit layer of the third carrier structure 30, and the third electronic element 27 is an active element, a passive element, or a combination of the active element and the passive element, etc., wherein the active element is such as a semiconductor chip, and the passive element is such as a resistor, a capacitor, or an inductor. In an embodiment, the third electronic element 27 is a semiconductor chip, and a plurality of (e.g., three as shown in FIG. 2) the third electronic elements 27 are disposed on the third carrier structure 30. It should be understood that there are many methods for the third electronic element 27 to be electrically connected to the third carrier structure 30, such as wire-bonding method, flip-chip method, embedding method, or other methods, and the present disclosure is not limited to as such.

In addition, the encapsulation layer 28 is formed on the third carrier structure 30 to encapsulate the third electronic elements 27, and the encapsulation layer 28 is made of an insulating material, such as polyimide (PI), dry film, epoxy resin, molding compound, or other packaging materials. The materials of the first cladding layer 24, the second cladding layer 25 and the encapsulation layer 28 may be the same or different.

In addition, the routing structure 33 includes at least one insulating layer (not shown) and a redistribution layer (RDL) (not shown) disposed on the insulating layer. For example, the material for forming the redistribution layer is copper, and the material for forming the insulating layer is a dielectric material such as polybenzoxazole (PBO), polyimide (PI), and prepreg (PP). It should be understood that the routing structure 33 and the third carrier structure 30 can be electrically connected to each other via at least one conductive structure (e.g., the copper pillar 17 shown in FIG. 1) formed in the encapsulation layer 28.

Therefore, a plurality of the package modules 2c stacked on each other can be arranged on the second side 20b of the first electronic module 2a according to requirements, and the outermost package module 2c can be disposed on a circuit board 9 via a plurality of first conductive elements 29a and second conductive elements 29b with different aspects, wherein an area between the outermost package module 2c and the circuit board 9 can be defined as a third interlayer L3, and the stress at the corners of the third interlayer L3 is greater than the stress at the corners of the second interlayer L2. For example, the first conductive elements 29a are solder balls of external connection specification (the amount of solder of the first conductive elements 29a are more than the amount of solder of the first conductive structures 31a, 31b). The second conductive elements 29b are copper core balls, and copper bumps 291 are encapsulated by solder materials 290.

It should be understood that because the solder balls have a large amount of solder and have better stress absorption capacity, so the first conductive elements 29a are arranged at the place where the stress of the third interlayer L3 is larger (such as the periphery or the corners), and the second conductive elements 29b with a smaller amount of solder are disposed at the place where the stress of the third interlayer L3 is smaller (e.g., in the middle). For example, the distribution pattern of the first conductive elements 29a surrounds the positions of the second conductive elements 29b.

To sum up, in the electronic package of the present disclosure, the first conductive structures and the second conductive structures (conductive structures with different solder amounts) can be arranged in the first interlayer according to the degree of warpage of the electronic package, so as to effectively disperse stress and avoid the problem of stress concentration. Therefore, the electronic package of the present disclosure can avoid the problem of warpage, thereby improving the yield of the electronic package on the circuit board subsequently.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a first electronic module having a first side and a second side opposing the first side;
a second electronic module stacked on the first side of the first electronic module, wherein an area between the first side of the first electronic module and the second electronic module is defined as a first interlayer, and an area outward from the second side of the first electronic module is defined as a second interlayer;
a plurality of first conductive structures having solder material and disposed in the first interlayer; and
a plurality of second conductive structures having solder material and disposed in the first interlayer, wherein a solder amount of the plurality of first conductive structures is greater than a solder amount of the plurality of second conductive structures.

2. The electronic package of claim 1, wherein each of the first conductive structures is a solder ball.

3. The electronic package of claim 1, wherein each of the second conductive structures includes a conductive pillar and a solder material formed on an end surface of the conductive pillar.

4. The electronic package of claim 1, wherein the plurality of first conductive structures and the plurality of second conductive structures are configured according to a magnitude of a stress in the first interlayer, such that a stress at positions where the plurality of first conductive structures are distributed in the first interlayer is greater than a stress at positions where the plurality of second conductive structures are distributed in the first interlayer.

5. The electronic package of claim 1, wherein the plurality of first conductive structures surround the plurality of second conductive structures.

6. The electronic package of claim 1, wherein the plurality of first conductive structures are further disposed in the second interlayer, and a number of the plurality of first conductive structures in the first interlayer is less than a number of the plurality of first conductive structures in the second interlayer.

7. The electronic package of claim 1, wherein the plurality of second conductive structures are further disposed in the second interlayer, and a number of the plurality of second conductive structures in the first interlayer is greater than a number of the plurality of second conductive structures in the second interlayer.

8. The electronic package of claim 1, further comprising a plurality of third conductive structures disposed in the first interlayer and free of having solder.

9. The electronic package of claim 8, wherein each of the third conductive structures includes a first conductive pillar and a second conductive pillar stacked on each other, wherein the first conductive pillar is erected on the first electronic module, and the second conductive pillar is erected on the second electronic module, such that an end surface of the first conductive pillar and an end surface of the second conductive pillar are in contact with each other in the first interlayer.

10. The electronic package of claim 8, wherein the plurality of first conductive structures, the plurality of second conductive structures and the plurality of third conductive structures are configured according to a magnitude of a stress in the first interlayer, such that a stress at positions where the plurality of first conductive structures are distributed in the first interlayer is greater than a stress at positions where the plurality of second conductive structures are distributed in the first interlayer, and a stress at positions where the plurality of second conductive structures are distributed in the first interlayer is greater than a stress at positions where the plurality of third conductive structures are distributed in the first interlayer.

11. The electronic package of claim 8, wherein the plurality of first conductive structures, the plurality of second conductive structures and the plurality of third conductive structures are sequentially arranged in a symmetrical manner from outside to inside in the first interlayer.

12. The electronic package of claim 8, wherein the plurality of second conductive structures surround the plurality of third conductive structures.

13. The electronic package of claim 8, wherein the plurality of third conductive structures are further disposed in the second interlayer, and a number of the plurality of third conductive structures in the first interlayer is equal to a number of the plurality of third conductive structures in the second interlayer.
